(19) United States
(12) Patent Application Publication
(10) Pub. No.: US 2008/0078446 A1
(43) Pub. Date: Apr. 3, 2008

(54) FLUID MIXING METHOD, MICRODEVICE AND MANUFACTURING METHOD THEREOF

(75) Inventor: Takayuki FUJIWARA, Minami-ashigara-shi (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM CORPORATION, Tokyo (JP)

(21) Appl. No.: 11/865,028

(22) Filed: Sep. 30, 2007

(30) Foreign Application Priority Data
Sep. 29, 2006 (JP) 2006-269528

(51) Int. Cl. B01F 5/00; B21D 51/16; B23P 17/04; B81B 1/00

(52) U.S. Cl. 137/3; 137/808; 29/890.09; 366/150.1; 366/165.1; 422/100

(57) ABSTRACT

In the fluid mixing method, a plurality of fluids are distributed through respective independent supply flow channels to come into confluence in a mixing field in microspace to mix with each other to form a mixed fluid, and the mixed fluid is discharged from the mixing field through a discharge flow channel. The fluid mixing method includes: a dividing step of dividing at least one of fluids to distribute; a flow contracting step of contracting the fluids after the dividing step immediately prior to confluence to the mixing field; a confluence step of bringing the contracted fluids into confluence so as to intersect at one point in the mixing field to mix the fluids; and a discharge step of discharging the mixed fluid from the mixing field.

### BACKGROUND OF THE INVENTION

1. Field of the Invention

The present invention relates to a fluid mixing method, a microdevice and a manufacturing method thereof, more particularly to a fluid mixing method wherein a plurality of fluids are distributed through respective independent supply flow channels and come to confluence to intersect in a mixing field, where the fluids are mixed (including reaction by mixing) and the mixed fluid is discharged from the mixing field, and a microdevice which carries out the method as well as a manufacturing method thereof.

2. Description of the Related Art

Japanese Patent Application Publication No. 2006-167600, for example, discloses a micromixer, as one of apparatuses for mixing a plurality of fluids efficiently, which supplies a mixing tank with fluid so that a swirling flow of fluid takes place in the mixing tank. However, in the case where, microscopic particles that are good in dispersiveness and extremely fine particles (emulsified silver microparticles, magnetic microparticles, organic pigment microparticles and the like), for example, are intended to be manufactured by mixing reaction, extremely uniform and rapid mixture is demanded, giving rise to such a problem that the micromixer of Japanese Patent Application Publication No. 2006-167600 is not sufficient.

On the other hand, a microdevice disclosed in Japanese Patent Application Publication No. 2005-288254 is configured to cause a plurality of fluids to come into confluence so as to intersect each other at one point of a microspacial mixing field and thereby be capable of uniform and instantaneous mixture. As illustrated in FIG. 11, the microdevice has supply channels 2 and 3, which supply a confluence region 1 with respective fluids A and B flowing into the microdevice, and a discharge channel 4, which discharges the confluent fluid C from the confluence region 1 to outside the microdevice. At least one of the supply channels 2 and 3 supplying one kind of fluid is configured to include a plurality of subchannels 2A and 2B, through which the fluid flows into the confluence region 1. The subchannels and the supply channels are formed so that a center axis of at least one of the plurality of subchannels 2A and 2B and a center axis of at least one of the channels for supplying the other kinds of fluid than the fluid that those subchannels supply intersect at one point 5.

Thus, in the case where mixture is carried out by distributing a plurality of kinds (for example, A and B) of fluid through respective independent flow channels to come into confluence so as to intersect in a mixing field of microspace, the case where the fluids A and B are divided into plurality (supply flow channels are divided) and supplied to the mixing field is more capable of improving mixing performance than the case where the fluids A and B are caused to be distributed through the respective supply flow channels (two channels in total) and supplied to the mixing field.

### SUMMARY OF THE INVENTION

However, in the case of the microdevice disclosed in Japanese Patent Application Publication No. 2005-288254, since the number of supply flow channels increases as division of fluid increases, an intention of connecting such increased supply flow channels to the mixing field gives rise to a problem that the volume of the mixing field cannot help getting larger. For example, in the case where the mixing field is formed as discoidal microspace and eight supply flow channels are connected to the mixing field radially, the mixing field formed circular in section has a circumference substantially the same as the total of flow channel diameters of the eight supply flow channels. Accordingly, the more the number of supply flow channels increases, the larger the sectional circle of the mixing field gets and the volume of the mixing field increases. Consequently, the volume of the mixing field gets too large and gives rise to a disadvantage that the original microspacial mixing field cannot be formed.

Theoretically, if the flow channel diameter of a supply flow channel is made small accompanied by increase in the number of supply flow channels, the diameter of the mixing field can be made small. However, the mixing field has to be formed as microspace, and supply flow channels with originally small channel diameter are used. Therefore, the use of a further smaller channel diameter will increase pressure loss and manufacturing thereof will become difficult as well.

Moreover, it is ideally desired to complete mixture of fluid only in the mixing field; however, even with the microdevice able to rapidly carry out mixture, the mixture is rarely completed among the mutual fluids only in the mixing field, and the discharge flow channel is also an important field for the mixture. However, the mixing field and the discharge flow channel have been regarded as different factors. Actually, measurement of both parties and relative positioning accuracy have not been considered.

Hence, in a microdevice mixing a plurality of fluids so as to intersect at one point in the mixing field and discharging the mixed fluid from the mixing field, a manufacturing method capable of increasing the relative positioning accuracy between a plurality of supply flow channels and the mixing field and relative positioning accuracy between the mixing field and the discharge flow channel is necessary.

The present invention has been contrived in view of such circumstances and an object thereof is to provide a microdevice and a fluid mixing method which can narrow the microspace being the mixing field for mixing a plurality of fluids; can mix the mutual fluids so as to intersect at one point in the narrow mixing field; and therefore can carry out uniform and rapid mixture.

Moreover, another object thereof is to provide a manufacturing method of a microdevice which can increase the relative positioning accuracy between a plurality of supply flow channels and the mixing field and relative positioning accuracy between the mixing field and the discharge flow channel; and, therefore, can ensure uniform and rapid mixture further.

In order to attain the aforementioned object, the present invention is directed to a fluid mixing method in which a plurality of fluids are distributed through respective independent supply flow channels to come into confluence in a mixing field in microspace to mix with each other to form a mixed fluid, and the mixed fluid is discharged from the mixing field through a discharge flow channel, the method comprising: a dividing step of dividing at least one of fluids to distribute; a flow contracting step of contracting the fluids after the dividing step immediately prior to confluence to the mixing field; a confluence step of bringing the contracted fluids into confluence so as to intersect at one point in the mixing field to mix the fluids; and a discharge step of discharging the mixed fluid from the mixing field.

According to this aspect of the present invention, in the flow contracting step, the respective fluids after the dividing step are contracted immediately prior to the confluence to the mixing field. Thereby, even if the number of supply flow channels increases by dividing the fluids in the dividing step, the microspace being the mixing field for mixture can be made narrow. Moreover, bringing the confluent fluids into impact and contact so as to intersect at one point in the mixing field, those fluids are segmentalized into smaller fluid bodies instantaneously by kinetic energy thereof and are improved in the mutual contact state among fluid bodies. Accordingly, the diffusion mixture distance among the mutual fluids can be made short by narrowing the mixing field with a contraction flow. Furthermore, the mutual fluids are mixed so as to intersect at one point in the narrow mixing field and are immediately discharged from the discharge flow channel. Therefore uniform and rapid mixture can be carried out.

Here, in description for the present invention, the mutual fluids are subjected to “mixing” in the mixing field, and the term “mixing” includes “reacting due to mixture”, which should be taken into account in the following description as well.

It is preferable that the mixing field is a discoidal microspace having a diameter of not more than 1 mm.

According to this aspect of the present invention, the shape and the size of the mixing field are specified, and the mixing field is preferably microspace with diameter being not more than 1 mm. Thereby, more uniform and rapid mixture can be carried out. Normally, by dividing the fluids, the number of supply flow channels increases. Therefore, the diameter of the mixing field (corresponding diameter) being not more than 1 mm is hardly attainable due to pressure loss and precision machining of channel but becomes attainable by providing the above described flow contracting step.

It is also preferable that in the discharge step, the mixed fluid to be discharged is contracted in a flow direction.

According to this aspect of the present invention, in the discharge step, by contracting the mixed fluid flow to be discharged in the flow direction, the diffusion mixture distance can be shortened. Thereby, even if mixture is not completed among the mutual fluids in the mixing field but mixture is going on in the discharge step, the mixture can be promoted since the mixture diffusion distance is short.

It is also preferable that the dividing step, the flow contracting step, the confluence step and the discharge step constitute each of a plurality of units of steps, and the plurality of units of steps are consecutively carried out.

This aspect of the present invention adopts the dividing step, the flow contracting step, the confluence step and the discharge step to make a single unit step, and the unit steps are consecutively carried out. Therefore, multistage reaction where fluid A and fluid B, for example, are mixed and brought into reaction, and then a reaction product C and fluid D are mixed and brought into reaction can be carried out. Accordingly, not only the reaction can be carried out in a multistage manner, but also various modes of mixture can be adopted corresponding with properties and nature of fluid for mixture (inclusive of reaction).

In order to attain the aforementioned object, the present invention is also directed to a microdevice, comprising: a plurality of independent supply flow channels through which a plurality of fluids are respectively distributed; a mixing field in microspace where the fluids distributed through the supply flow channels come into confluence to mix with each other to form a mixed fluid; and a discharge flow channel through which the mixed fluid is discharged from the mixing field, wherein: the supply flow channels include divided supply flow channels divided into a plurality of channels so as to divide at least one of the fluids into a plurality of fluid parts to be distributed; the supply flow channels including the divided supply flow channels are radially arranged around the mixing field so that center axes of the supply flow channels intersect at one point in the mixing field; at least a part of ends of the supply flow channels connected to the mixing field, taperings are formed so as to contract flows of the fluids; and the taperings are formed to provide a corresponding diameter D1 of a virtual circle depicted by connecting the ends of the radially arranged supply flow channels each other being smaller than a corresponding diameter D2 of a virtual circle depicted by connecting ends of the radially arranged supply flow channels each other without forming the taperings.

This aspect of the present invention configures the present invention as an apparatus and can narrow microspace being the mixing field even if the number of supply flow channels increases by dividing a plurality of fluids since at least a part of end parts (in the vicinity of ports in communication with the mixing field) of a plurality of supply flow channels where each fluid to be confluent to the mixing field is distributed is tapered. Thereby, the mutual diffusion mixture distance among the fluids can be shortened. Moreover, the mutual fluids are mixed so as to intersect at one point in the narrow mixing field and are immediately discharged from the discharge flow channels. Therefore uniform and rapid mixture can be carried out.

Here, in the present specification, the term “tapering” means not only “a state and a portion where a diameter gradually decreases conically” but also “an inclined portion which is inclined inward a flow channel”, which will be applicable in the following description. Accordingly, “tapering is formed at least one part of an end part of a supply flow channel” means that at least one side among four sides inclines inward to form tapering in the case where the channel section of the supply flow channel is quadrangular.

It is preferable that the mixing field is a discoidal microspace having a diameter of not more than 1 mm.

According to this aspect of the present invention, the mixing field is a microspace with the diameter being not more than 1 mm. Thereby more uniform and more rapid mixture can be carried out.

It is also preferable that each of the ends of the supply channels is tapered to narrow a width of the flow channel and is formed to compensate decrease in a flow channel cross-sectional area by deepening a depth of the flow channel.

According to this aspect of the present invention, the end parts of the respective supply channels are tapered to narrow the flow channel width and are formed to compensate a decrease in flow channel cross-sectional area by deepening the flow channel depth. Therefore, even if the number of supply channels increases by dividing the fluids, the microspace being the mixing field for mixture can be narrowed. Moreover, pressure loss in the flow channels can be made not to increase.

It is also preferable that the corresponding diameter D1 is equal to a diameter D3 of a flow channel cross-section of the discharge flow channel.

According to this aspect of the present invention, the diameter of the mixing field and the diameter of the flow channel cross-section of the discharge flow channel are the same. Therefore, the diffusion mixture distance in the discharge flow channel can be shortened. Thereby, even if combination is not completed among the fluids each other in the mixing field but mixture is going on in the discharge step, the mixture can be promoted since the diffusion mixture distance is short.

It is also preferable that the discharge flow channel is formed to taper in a flow direction of the mixed fluid.

According to this aspect of the present invention, the diffusion mixture distance in the discharge flow channel can be shortened. Thereby, even if combination is not completed among the fluids each other in the mixing field but mixture is going on in the discharge step, the mixture can be promoted since the diffusion mixture distance is short.

It is also preferable that directions of the taperings are adjusted so as to generate a swirling flow in the mixing field without moving the center axes of the supply flow channels.

According to this aspect of the present invention, the direction of the tapering is adjusted so as to generate a swirling flow in the mixing field without moving the center axes of the respective supply flow channels. Therefore, the end parts of the respective supply flow channels can bring the fluids into confluence so as to intersect at one point in the mixing field and, moreover, can generate a swirling flow in the mixing field. Thereby, further promotion of mixtures can be designed.

In order to attain the aforementioned object, the present invention is also directed to a microdevice configured by connecting a plurality of microdevices in series, each of the microdevices being the above-described microdevice.

According to this aspect of the present invention, division, flow contraction, confluence and discharge of fluid can make a single unit to carry out the unit steps in a multistage. Therefore, fluid A and fluid B, for example, can be mixed and brought into reaction, and a reaction product and fluid C can be mixed and brought into reaction. Accordingly, not only that the reaction can be carried out in a multistage manner, but also various modes of mixture can be adopted corresponding with properties and nature of fluid to undergo mixture (including reaction).

In order to attain the aforementioned object, the present invention is also directed to a manufacturing method of a confluent block and a discharge block among a plurality of plate-like blocks which constitute a microdevice in which a plurality of fluids are distributed through respective independent supply flow channels to come into confluence in a mixing field in microspace to mix with each other to form a mixed fluid, and the mixed fluid is discharged from the mixing field through a discharge flow channel, the confluent block forming the mixing field and the supply flow channels in communication with the mixing field, the discharge block forming the discharge flow channel, the method comprising: a first step of temporarily binding, with a temporary joint device, the confluent block and the discharge block prior to processing with mutual plate surfaces being matched together; a second step of forming a plurality of pin holes on the confluent block and the discharge block temporarily bound, the pin holes to be used for detachably binding the confluent block and the discharge block with pins; a third step of inserting the pins into the pin holes to bind the confluent block and the discharge block, and removing the temporary joint device; a fourth step of forming a hole from a center position on a plate surface on a side of the discharge block to midway the confluent block bound with the pins, to form the discharge flow channel and the mixing field with center axes thereof being matched together; a fifth step of temporarily disassembling the discharge block and the confluent block to remove the discharge block from the confluent block; a sixth step of forming flow channel grooves in a same number as the supply flow channels, on a plane surface of the confluent block on a side of the discharge block radially from the center axis of the mixing field formed in the fourth step; and a seventh step of reassembling the confluent block and the discharge block by binding with the pins.

According to this aspect of the present invention, in the first to third steps, pins and pin holes for positioning both of the confluent block and the discharge block correctly when both parties are disassembled and assembled are formed to bring both parties into pin binding.

Next, in the fourth to fifth steps, in the state where the confluent block and the discharge block are bound with the pins, a hole is provided from the center position on the plate plane on the side of the discharge block to the midway of the confluent block to form the discharge flow channel and the mixing field concurrently to make the center axes thereof match together. Then, the confluent block and the discharge block are temporarily disassembled.

Next, in the sixth to the seventh steps, the same number of flow channel grooves as the number of the supply flow channel is formed to radiate from the center axis of the mixing field on the plane on the side of the discharge block of the confluent block and then both parties are assembled again. Thereby the mixing field, the supply flow channel and the discharge flow channel are formed.

Thus, in the state where the confluent block and the discharge block are detachably bound with the pins and the pin holes so as to improve accuracy in positioning at occasions of disassembling and assembling the confluent block and the discharge block, at first, the mixing field and the discharge flow channel are formed so as to bring the center axes of the mixing field and the discharge flow channel into matching. Thereafter the supply flow channel is formed radially from the center axis of the mixing field. Therefore, accuracy in relative position between a plurality of supply flow channels and the mixing field and accuracy in relative position between the mixing field and the discharge flow channel can be intensified. Thereby, a microdevice enabling uniform and rapid mixture can be produced.

As described above, according to the fluid mixture method and the microdevice of the present invention, the microspace being the mixing field for mixing a plurality of fluids can be narrowed and the mutual fluids can be mixed so as to intersect at one point in the narrow mixing field. Therefore, uniform and rapid mixture can be carried out.

In addition, according to the manufacturing method of the microdevice of the present invention, accuracy in the relative position between a plurality of the supply flow channels and the mixing field and accuracy in the relative position between the mixing field and the discharge flow channel can be intensified. Therefore the uniform and rapid mixture can be further ensured.

### BRIEF DESCRIPTION OF THE DRAWINGS

The nature of this invention, as well as other objects and advantages thereof, will be explained in the following with reference to the accompanying drawings, in which like reference characters designate the same or similar parts throughout the figures and wherein:

FIG. 1 is an exploded perspective diagram of a microdevice according to an embodiment of the present invention;

FIGS. 2A and 2B are explanatory diagrams for illustrating diffusion mixture distance getting shortened by dividing fluid in a mixing field;

FIGS. 3A and 3B are explanatory diagrams for illustrating a flow channel end part of a supply flow channel in the case of tapering in comparison to the case of not tapering;

FIGS. 4A and 4B are explanatory diagrams for illustrating diffusion mixture distance getting shortened in one of the mixing field and the discharge flow channel by tempering;

FIGS. 5A and 5B are diagrams for illustrating tapering at a flow channel end part of a supply flow channel;

FIGS. 6A and 6B are diagrams for illustrating tapering without changing flow channel cross-sectional area;

FIG. 7 is an explanatory diagram for illustrating a method of tapering for forming a swirling flow in the mixing field;

FIG. 8 is a diagram for illustrating a concept of tapering the discharge flow channel;

FIG. 9 is an exploded perspective diagram of a microdevice according to another embodiment of the present invention;

FIGS. 10A to 10F are diagrams for illustrating a manufacturing method of the microdevice; and

FIG. 11 is a diagram for illustrating a micro device in the related art.

### DETAILED DESCRIPTION OF THE PREFERRED EMBODIMENTS

A fluid mixing method, a microdevice and a manufacturing method thereof according to preferable embodiments of the present invention will be described with reference to the accompanying drawings below.

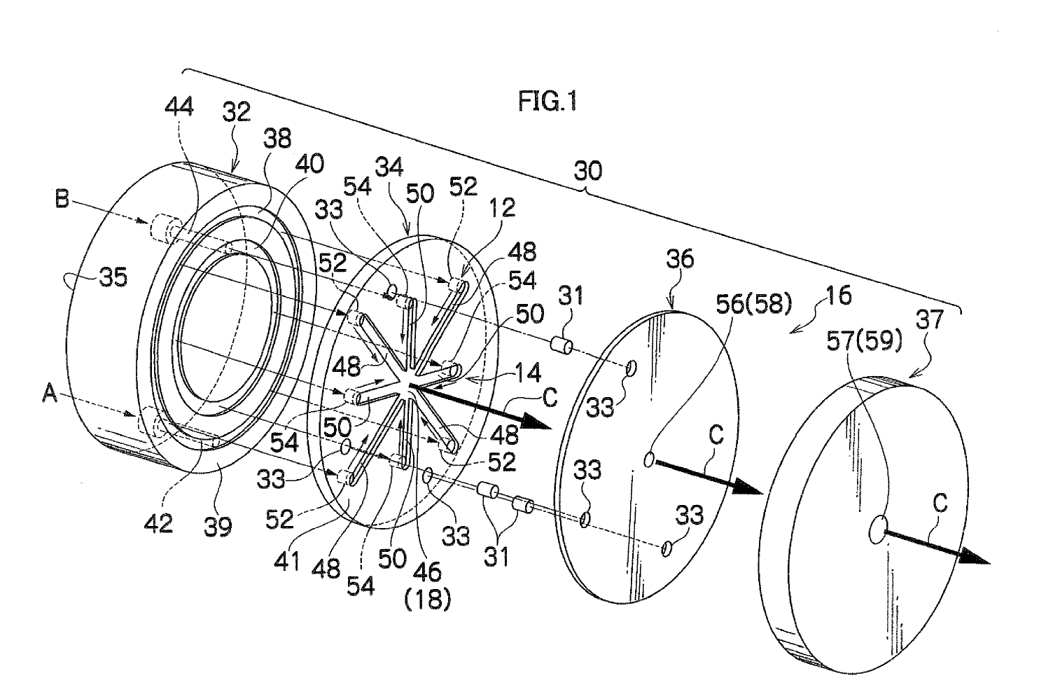

FIG. 1 is a diagram of a microdevice according to an embodiment of the present invention, and is an exploded perspective diagram for illustrating an exploded state of four parts in a perspective diagram. The present embodiment will be described with two fluids A and B but will not be limited thereto. Three or more kinds can be adopted.

A microdevice 30 of the present embodiment is configured by putting a plurality of fluids A and B in circulation through respective independent supply flow channels 12 and 14; making confluence in the mixing field 18 of microspace to mix the fluids together; and discharging the mixed fluid C subjected to mixture from the mixing field 18 through the discharge flow channel 16. The structure thereof will be described below.

Here, the fluid includes liquid and a liquid mixture allowing handling as liquid. Objects to be mixed include a solid and/or liquid containing gas, that is, microsolid such as powder (for example, metal microparticles) and/or a liquid compound containing microbubbles, for example. Moreover, the liquid can contain the other kinds of undissolved liquid and can be, for example, an emulsion. Furthermore, the fluid can be gas and can contain microsolid in gas.

As described in FIG. 1, the microdevice 30 is configured mainly by a supply block 32, a confluent block 34, a first discharge block 36 and a second discharge block 37, which are respectively discoidally shaped. In order to assemble the microdevice 30, the confluent block 34 and the first discharge block 36 among those discoidal blocks 32, 34, 36 and 37 are bound with a plurality of pins 31 and pin holes 33 in advance and four blocks 32, 34, 36 and 37 are fixed integrally with bolts (not shown) in that state. Accordingly, in the respective blocks in FIG. 1, besides the above described pin holes 33, bolt holes (not shown) are formed.

The supply block 32 has two annular grooves 38 and 40 concentrically formed on a side plane 39 facing the confluent block 34. In the state of assembling the microdevice 30, the two annular grooves 38 and 40 form ring-like flow channels where the fluid A and the fluid B flow respectively. The supply block 32 has through holes 42 and 44, which reach the outer annular groove 38 and the inner annular groove 40 from the side plane 35 on the opposite side not facing the confluent block 34 of the supply block 32. In such two through holes 42 and 44, the through hole 42 which is communicated to the outer annular groove 38 is connected to a supply device (such as a pump and a connection tube, not shown) which supplies the fluid A. The through hole 44 which is communicated with the inner annular groove 40 is connected to a supply device (such as a pump and a connection tube, not shown) which supplies the fluid B. In FIG. 1, the fluid A flows in the outer annular groove 38 and the fluid B flows in the inner annular groove 40. However, the combination thereof can be switched.

The confluent block 34 has a discoidal confluent hole 46 formed in the center of the side plane 41 facing the first discharge block 36. Four long radial grooves 48 and four short radial grooves 50 are alternately arranged radially from the confluent hole 46. For those confluent hole 46 and radial grooves 48 and 50, in the state of assembling the microdevice 30, the confluent hole 46 becomes the mixing field 18 so that the radial grooves 48 and 50 form radial flow channels where the fluid A and the fluid B flow.

The confluent block 34 has through holes 52 formed from the distal ends of the long radial grooves 48 to the direction of thickness of the confluent block 34. The through holes 52 are communicated with the above described outer annular groove 38 formed in the supply block 32. The confluent block 34 has through holes 54 formed from the distal ends of the short radial grooves 50 to the direction of thickness of the confluent block 34. The through holes 54 are communicated with the inner annular groove 40 formed in the supply block 32.

In the center of the first discharge block 36, one through hole 56 is formed in the direction of thickness of the first discharge block 36. The through hole 56 becomes the first discharge flow channel 58. Moreover, in the center of the second discharge block 37, one through hole 57 is formed in the direction of thickness of the second discharge block 37. The through hole 57 becomes the second discharge flow channel 59. The discharge flow channel 16 including the first discharge flow channel 58 and the second discharge flow channel 59 is communicated with the mixing field 18. In that case, the first discharge flow channel 58 is preferably formed so as to be slender than the second discharge flow channel 59 in flow channel diameter.

The above described configuration causes the fluid A to flow in the supply flow channel 12 configured by the through hole 42 of the supply block 32, the outer annular groove 38, the through hole 52 of the confluent block 34 and the long radial groove 48 in this order to be divided into four divided flows and to reach the mixing field 18 (confluent hole 46). On the other hand, the fluid B flows in the supply flow channel 14 configured by the through hole 44 of the supply block 32, the inner annular groove 40, the through hole 54 of the confluent block 34 and the short radial groove 50 in this order to be divided into four divided flows and to reach the mixing field 18 (confluent hole 46). Then, the mixed fluid C mixed in the mixing field 18 is discharged from the mixing field 18 through the discharge flow channel 16.

Thus, the two fluids A and B are divided into eight fluid parts. Thereby, diffusion mixture distance M between the mutual fluid parts in the mixing field 18 can be shortened and thereby mixture is promoted.

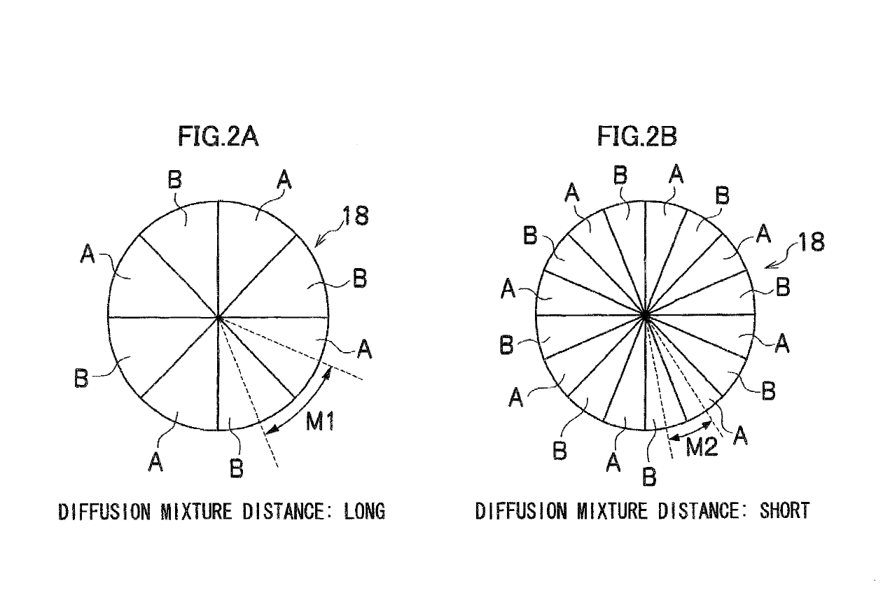

FIGS. 2A and 2B are diagrams for illustrating a concept of difference in diffusion mixture distance M in the mixing field 18 by division of the fluid A and the fluid B (that is, division of the supply flow channels 12 and 14). FIG. 2A illustrates the fluid A and the fluid B of two kinds divided into eight fluid parts in total to give diffusion mixture distance M1.

FIG. 2B illustrates the fluid A and the fluid B divided into 16 fluid parts in total to give diffusion mixture distance M2. As apparent from comparison between FIG. 2A and FIG. 2B, the diffusion mixture distance M2 gets shorter to be a half of the diffusion mixture distance M1.

The divided flow of the fluid A and the divided flow of the fluid B provided with kinetic energy respectively come into confluence in the mixing field 18. The mixed fluid mixed after confluence changes the flow direction by 90° and is discharged from the mixing field 18 through the first discharge flow channel 58 and the second discharge flow channel 59.

In the microdevice 30, as illustrated in FIG. 1, the confluent block 34 and the first discharge block 36 are bound together with the pins 31. That is, in the circumferential position in the state where the confluent block 34 and the first discharge block 36 are fit together, pin holes 33 (three pin holes each in FIG. 1 totaling six pin holes) are formed respectively. The pins 31 are inserted into the pin holes 33. Thereby the confluent block 34 and the first discharge block 36 are bound together with the pins 31. As for advantages of that pin binding will be described when the manufacturing method of the microdevice 30 is described later.

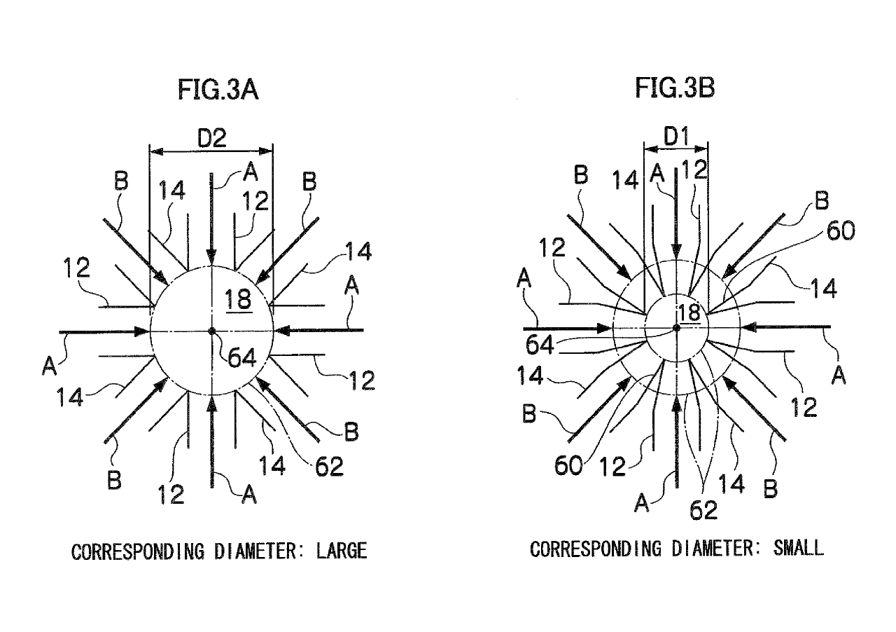

In the microdevice 30, as illustrated in FIG. 3B, at the ends of the eight supply flow channels 12 and 14 connected to the mixing field 18, tapering 60 is formed at least one part of the end part so as to contract the flows of the fluid A and the fluid B.

As apparent from contrast between FIGS. 3A and 3B, the taperings 60 provide a corresponding diameter D1 of a virtual circle 62 depicted by connecting the flow channel ends each other in the eight radially arranged supply flow channels 12 and 14 being smaller than the corresponding diameter D2 of a virtual circle 62 depicted by connecting the flow channel ends each other in the eight radially arranged supply flow channels 12 and 14 without forming any tapering 60.

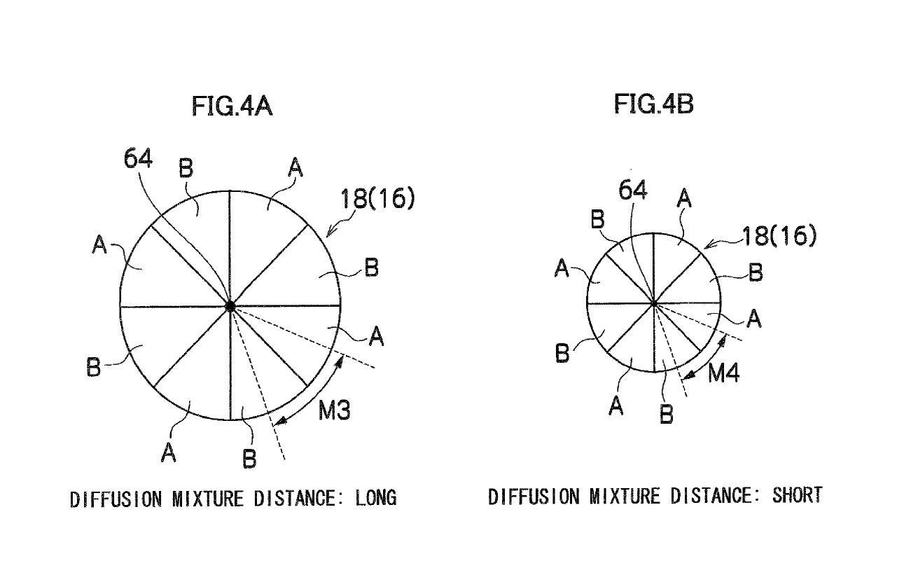

Thereby, as apparent from contrast between FIGS. 4A and 4B, by dividing the fluid A and the fluid B, even if the number of the supply flow channels 12 and 14 increases from two to eight, the microspace being the mixing field 18 for mixture can be narrowed. Consequently, as in FIG. 4B, diffusion mixture distance M4 between the fluid A and the fluid B get shorter than diffusion mixture distance M₃ in FIG. 4A.

In description with a specific example, in the case where the flow channel cross-section of the supply flow channels 12 and 14 are formed to be quadrangular with width and depth being 200 μm respectively, the corresponding diameter D2 of the mixing field 18 in FIG. 3A without forming any tapering 60 becomes 523 μm. On the other hand, as in the case of the microdevice 30 of the present embodiment illustrated in FIG. 3B, forming the taperings 60 at the end parts of the supply flow channels 12 and 14 connected to the mixing field 18 to make the width of the supply flow channels 12 and 14 to 100 μm, the corresponding diameter D1 becomes 261 μm and decrease by half in the case where there is no tapering 60.

The intersection 64 in the mixing field 18 is the center of the corresponding diameter and is a point at the intersection of the vector of the fluid A with the vector of the fluid B flowing into the mixing field 18. If the flows do not intersect at one point, the center of gravity of one of polygon (or cube) formed by the vectors of flows is preferably set to the center of the corresponding diameter. Here, the flow channel cross-section of the supply flow channels 12 and 14 is preferably quadrangular shape but do not have to be regulated in particular. In the case where the material of stainless steel undergoes an etching process, the flow channel cross-section becomes semicircular. The present embodiment is effective for such a shape as well.

Moreover, as in the present embodiment, by forming the taperings 60 at the flow channel end parts of the supply flow channels 12 and 14 connected to the mixing field 18 to narrow the flow channel width only of the flow channel end parts, the pressure loss caused by flowage can be reduced compared with the case of narrowing the entire width of the supply flow channels 12 and 14.

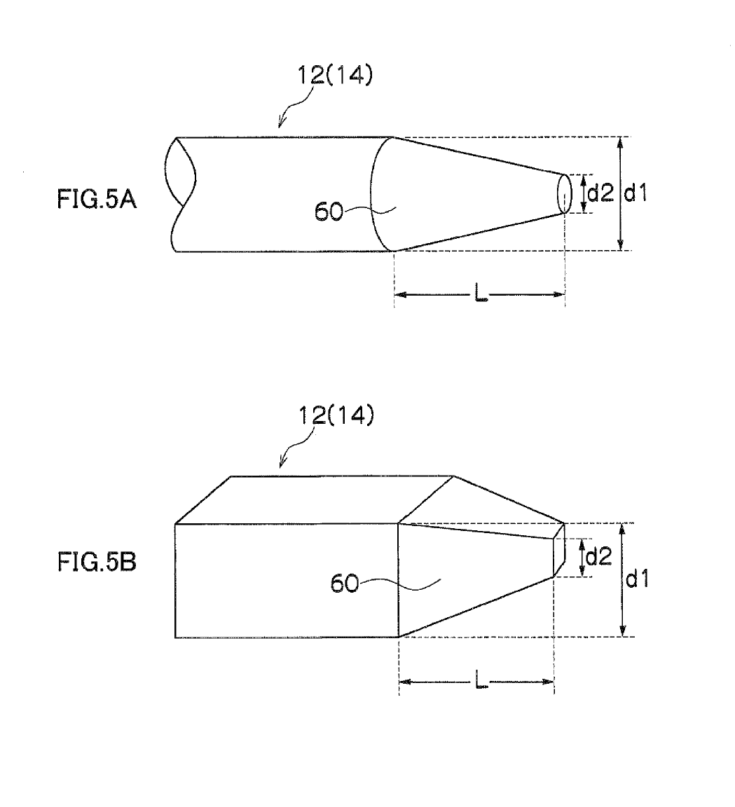

As a rough guide for forming the taperings 60 at the flow channel end parts of the supply flow channels 12 and 14, as illustrated in FIGS. 5A and 5B, the ratio of the contracted portion ΔD (=d1-d2) of the flow channel width to the distance L in the flow direction, i.e., the ratio ΔD/L preferably falls within a range of 0.1 to 100 and more preferably the ratio ΔD/L falls within a range of 1 to 10.

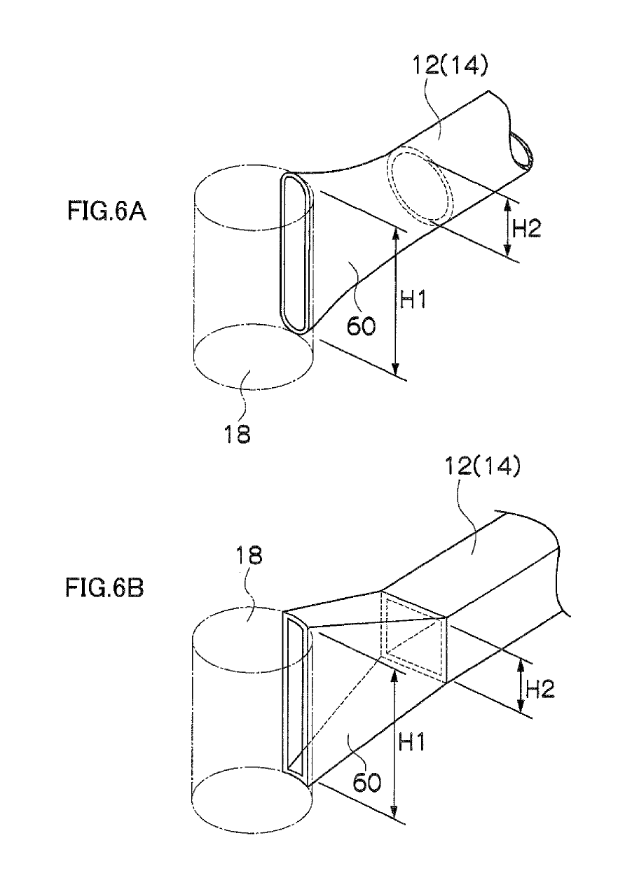

However, in the case where the number of division of the fluid A and the fluid B is large (not less than eight, for example) and the supply flow channels 12 and 14 themselves are required to get further slender in order to narrow the mixing field 18, the pressure loss occasionally gets larger even if the taperings 60 are formed only at the flow channel end parts. Moreover, in order to increase an interfacial area in a contact interface between the fluid A and the fluid B, not the flow channel width but the flow channel depth had better be increased. Therefore, in that case, as illustrated in FIGS. 6A and 6B, the flow channel end parts of the respective supply flow channels 12 and 14, the flow channel width of which is narrowed by the tapering 60, are formed so as to compensate the decrease in the flow channel cross-sectional area due to that narrowed width by making the flow channel depth H1 of the flow channel end part deeper than the other flow channel depth H2. Thereby, contribution to an increase in the interfacial area is available and the pressure loss due to flowage can be decreased. In that case, in order not to generate a detention part of the fluid A and the fluid B in the supply flow channels 12 and 14, the flow channel cross-sectional area from the entrances of the supply flow channels 12 and 14 to the place connected to the mixing field 18 is preferably kept constant.

Moreover, by forming the taperings 60 at the flow channel end parts of the supply flow channels 12 and 14 to narrow the flow channel width, flow velocities of the fluid A and the fluid B flowing into the mixing field 18 can be raised. Thereby, mixture can be promoted and in the case where mixture deposits a reaction product, disturbance caused by attachment of the precipitate onto the wall surfaces of the flow channel end parts can be restrained. Furthermore, forming a narrow width part with narrowed flow channels midway of the supply flow channels 12 and 14, the narrow width part functions as orifices so as to enable distribution of the fluid A and the fluid B evenly to the supply flow channels being present in plurality.

In the microdevice 30 of the present embodiment, the shape of the mixing field 18 formed to be narrow is preferably discoidal microspace. Moreover, from the mixing field 18 to the discharge flow channel 16, the measurement of the portion which influences mixture is preferably a flow channel measurement with the value of the Reynolds number at an occasion of causing fluid to flow being not more than 2300. More specifically, depending on flow rate and viscosity of the fluid A and the fluid B, the upper limit of the flow channel measurement is preferably not more than 1 mm in corresponding diameter and more preferably not more than 600 μm in the case of quick mixture. The lower limit of the flow channel measurement is preferably not less than 1 μm from the point of view of pressure loss of fluid and the process method. Here, the corresponding diameter is a diameter in the case where the flow channel cross-section is circular.

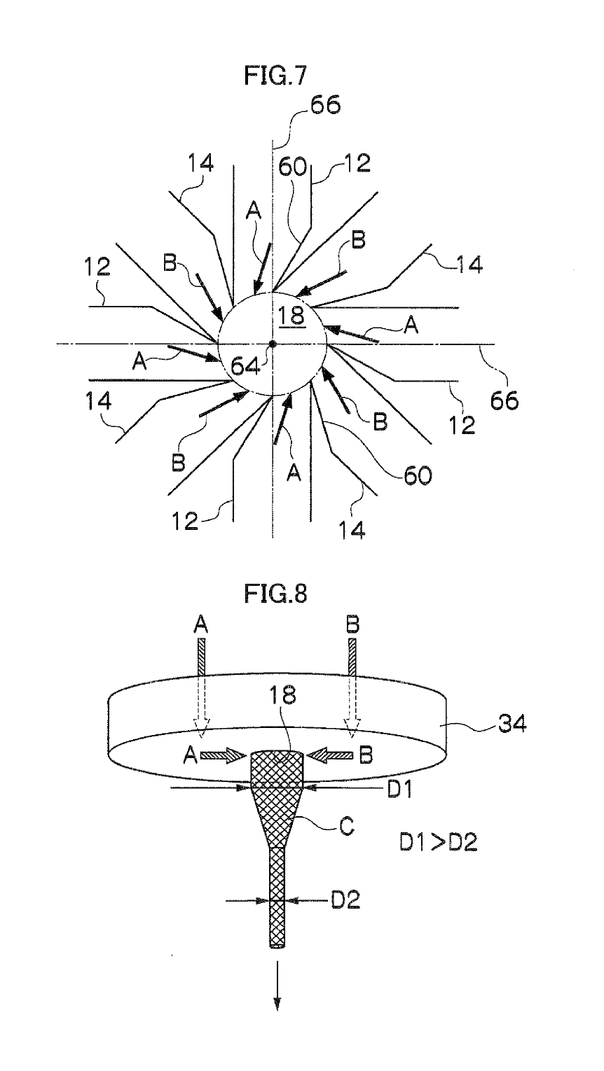

As shown in FIG. 7, it is more preferable for uniform and rapid mixture that the directions of the tapering 60 are adjusted without moving the center axis 66 of the eight supply flow channels 12 and 14, so as to generate a swirling flow in the mixing field 18. As a specific example, the taperings 60 are formed by causing only one side in the opposite sides in the width direction among four sides of quadrangular shape of the flow channel cross-section of the supply flow channels 12 and 14 to incline inward. Thereby, even if the number of the supply flow channels 12 and 14 increases by dividing the two fluids into eight fluid parts, the microspace being the mixing field 18 for mixture can be narrowed. Moreover, bringing the confluent fluids into impact and contact so as to intersect at one point in the mixing field 18, those fluid parts are segmentalized into smaller fluid bodies instantaneously by kinetic energy provided thereby and the mutual contact state among fluid bodies is improved. Accordingly, the mutual diffusion mixture distance among the fluids in the mixing field can be made short. Furthermore, the mutual fluids are mixed so as to intersect at one point in the narrow mixing field and are immediately discharged from the discharge channel. Therefore uniform and rapid mixture can be carried out.

The above description is concerned with the supply flow channels 12 and 14 and the mixing field 18, and the discharge flow channel 16 is preferably arranged as follows. That is, the diameter D1 of the mixing field 18 and the diameter D3 of the flow channel cross-section of the first discharge flow channel 58 in particular are preferably the same. Thereby, at an occasion when the mixing field 18 in FIG. 4B is replaced by the flow channel cross-section of the first discharge flow channel 16, the diffusion mixture distance M4 can be shortened. Accordingly, even if combination is not completed among the fluids each other in the mixing field 18 but mixture is going on in the discharge flow channel 16, the mixture can be promoted since the diffusion mixture distance is short. Moreover, as illustrated in FIG. 8, the discharge flow channel 16 is formed to make a tapered shape (i.e., D1>D2) in the flow direction of the mixed fluid C. Thereby the laminar flow of the mixed fluid C which flows in the discharge flow channel 16 is made thinner. Thereby, diffusion time is shortened so that more rapid mixture is realizable.

The microdevice 30 configured as described above can be manufactured by utilizing high-precision processing technologies such as microdrill processing, microdischarge processing, molding that utilizes plating, injection molding, dry etching, wet etching and hot embossing. Moreover, a machining technique that uses a general-use lathe and drilling machine can be utilized. For example, as for the flow channels of the supply flow channels 12 and 14, only the portions of the taperings 60, which are formed in the flow channel end parts, are formed by microdischarge processing and for the other portions, microdrill processing is preferably used.

Material of the microdevice 30 is not limited in particular but preferably allows application of the above-described process techniques. More specifically, metal material (iron, aluminum, stainless steel, titanium, various kinds of metal and the like), resin material (fluoride resin, acrylic resin and the like) and glass (silicon, heat-resistant and chemical-resistant glass, quartz and the like) can be used.

As described above, in the present embodiment, the supply block 32, the confluent block 34, the first discharge block 36 and the second discharge block are linked with the bolt 44. O-rings are preferably used between the mutual blocks for preventing the fluid A and the fluid B from leaking. However, the assembly method is not limited thereto. For example, utilization of intermolecular force on the member surfaces of the mutual blocks and utilization of direct bonding with adhesive is feasible. By utilizing direct bonding, the O-rings are omittable so as to enable application to fluid which erodes rubber material. In the case of silicon and heat-resistant and chemical-resistant glass, thermal expansion coefficients of the material are close and therefore heat direct bonding is feasible. On the other hand, in the case of bonding materials with different thermal expansion coefficients, irradiating argon ion beam and the like onto members in the vacuum to clean the surface of the members on an atomic level and thereby normal temperature direct bonding (surface activation bonding technologies) to carry out pressure bonding at a normal temperature is utilizable. The normal temperature direct bonding technology is advantageous in enabling alleviation of thermal stress in the case of configuring the material with different material. Here, by carrying out direct bonding, the microscale supply flow channels 12 and 14, the mixing field 18 and the discharge flow channel 16 and the like are freed from the risk of being blocked by protrusion of adhesive.

Supplying device which supplies the microdevice 30 with the fluid A and the fluid B requires a fluid control function which controls the flow of the fluid A and the fluid B. In particular, behavior of the fluid in microscale supply flow channels 12 and 14, the mixing field 18, and the discharge flow channel 16 has different properties from the macroscale. Therefore, a control system appropriate for microscale has to be considered. The fluid control system includes a continuous flowage system and a droplet (liquid plug) system in classification by mode, and includes an electric drive system and a pressure drive system in classification by drive power.

Among those systems, the continuous flowage system is the most widely used. Generally in the fluid control in the continuous flowage system, the interior of the micro flow channel 16 is entirely filled with fluid and the entire fluid is driven by a pressure source such as syringe pump made ready in the outside. Large dead volume is a drawback of that method, which, however, is significantly advantageous since the control system is realizable with a comparatively simple set up.

Moreover, the temperature control of the microdevice 30 can be carried out by putting the entire device into a temperature controlled container. It is also possible that a heater structure such as metal resistance lines and polysilicon is installed inside the device, and a thermal cycle is carried out by using the heater structure for heating and natural cooling for cooling. As for temperature sensing, in the case of using the metal resistance lines, another resistance line the same as in the heater is installed internally in advance. Then temperature is preferably measured according to the change in resistance value thereof. In the case of using polysilicon, a thermocouple is preferably used to carry out temperature measurement. Moreover, by causing a Peltier device to contact the flow channel, heating and cooling can be carried out from outside. Thereby, the diffusion velocity is accelerated to enable rapid mixture. Moreover, incorporating the cooling device into the microdevice 30 and rapidly heating/rapidly cooling the desired sites, stability of mixture (reaction) can be improved.

The number of the microdevice 30 used in the present embodiment can be, of course, one. Corresponding with necessity, a plurality of the microdevices 30 are aligned in series to enable multistage mixture. Alternatively, a plurality of the microdevices 30 can be aligned in parallel (numbering up) so as to enable an increase in the process amount thereof.

Next, with the microdevice 30 as configured as described above, the fluid mixture method of the present embodiment will be described.

The fluid mixture method of the present embodiment is mainly configured by four steps including a dividing step, a flow contracting step, a confluence step and a discharge step.

In the dividing step (in the supply block), the fluid A and the fluid B are divided into four fluid parts respectively, that is, eight fluid parts in total and are distributed. Thereby, since diffusion mixture distance at an occasion of bringing the eight parts of the fluid A and the fluid B into confluence in the mixing field 18 becomes remarkably shorter than diffusion mixture distance at an occasion of bringing the two fluid A and fluid B directly into confluence in the mixing field 18, mixture is promoted.

Next, in the flow contracting step (in the confluent block), the eight fluid parts after the dividing step are contracted immediately before confluence into the mixing field 18. Thereby, by dividing the two fluids into the eight fluid parts, even if the number of the supply flow channels 12 and 14 increases, the microspace being the mixing field 18 for mixture can be narrowed.

Next, in the confluence step (in the confluent block), the contracted eight fluid parts are brought into confluence so as to intersect at one point (intersection) 64 in the mixing field 18 and thereby the mutual fluids are mixed. Thus, by bringing the confluent eight fluid parts A and B into impact and contact so as to intersect at one point 64, those fluid parts A and B are segmentalized into smaller fluid bodies instantaneously by kinetic energy provided thereby and the mutual contact state among fluid bodies is improved.

Accordingly, in the flow contracting step, the mutual diffusion mixture distance among the fluids in the mixing field 18 can be made short. In the confluence step, the mutual fluids are mixed so as to intersect at one point 64 in the mixing field 18. Therefore uniform and rapid mixture can be carried out.

Next, in the discharge step (in the discharge block), the mixed fluid is discharged from the mixing field 18. In that case, the discharge block is divided into the first discharge block and the second discharge block, the diameter D3 of the exit flow channel formed in the first discharge block is the same as the diameter D1 of the mixing field 18. Even if mixture is not completed among the fluids each other in the mixing field but mixture is going on in the discharge step, the mixture can be promoted since the diffusion mixture distance is short. The discharge flow channels are more preferably formed to taper in the flow direction of the mixed fluid. Moreover, in particular, the directions of the taperings 60 are preferably adjusted so as to generate a swirling flow in the mixing field 18.

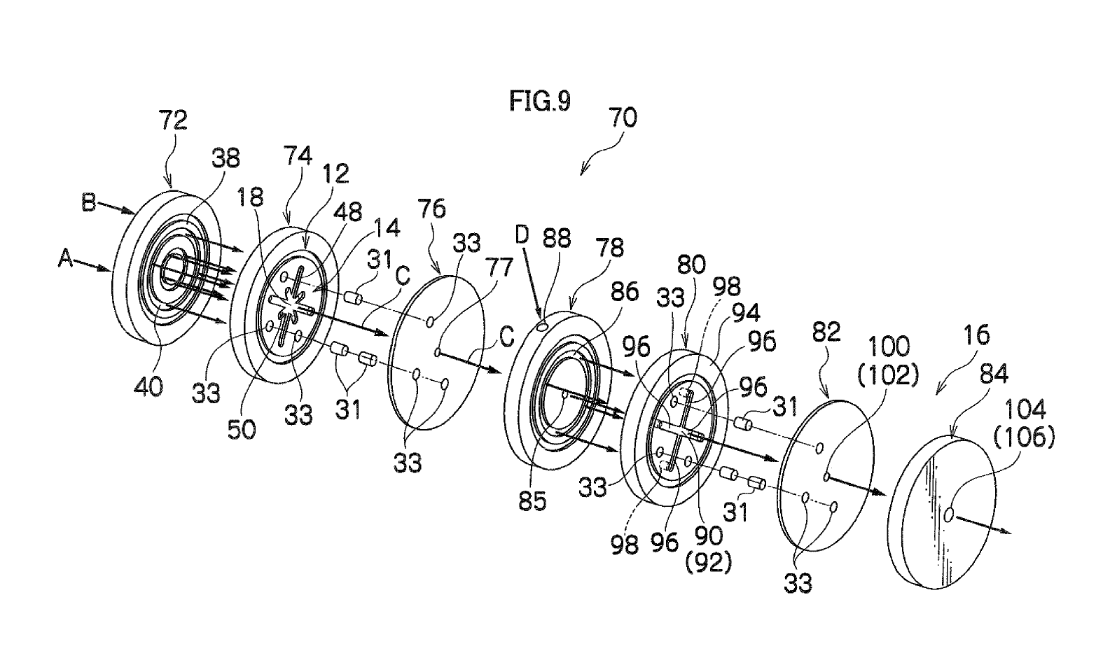

FIG. 9 illustrates a microdevice according to another embodiment of the present invention, and is an exploded diagram for illustrating the above described microdevices configured by linking two stages in series. The number of stages aligned in series is not be limited to two stages but can be more than two stages.

A microdevice 70 in FIG. 9 is configured mainly by a first supply block 72, a first confluent block 74, a first discharge block 76 and a second supply block 78, a second confluent block 80, a second discharge block 82 and a third discharge block 84, which are respectively discoidally shaped.

Here, since the first supply block 72, the first confluent block 74 and the first discharge block 76 are likewise the supply block 32, the confluent block 34 and the first discharge block 36 described with reference to FIG. 1, the description thereof will be omitted. Therefore, the other blocks are described below.

At the center axis of the discoidal second supply flow block 78, a through hole 85 in communication to the discharge flow channel 77 of the first discharge block 76 is formed. The mixed fluid C is supplied to the through hole 85. On the other hand, one annular groove 86 is formed in the second supply block 78 around the center axis of the second supply block 78 as the center. By matching the second supply block 78 and the second confluent block together, a ring-like flow channel is formed. A through hole 88 in communication to the annular groove 86 is formed on the circumferential surface of the second supply block 78. The fluid D is supplied from the through hole 88 to the annular groove 86.

A confluent hole 90 in communication to the through hole 85 of the second supply block 78 is formed at the center axis of the second confluent block 80. The confluent hole 90 becomes the mixing field 92 for mixture in which the mixed fluid C and the new fluid D come into confluence. Moreover, four radial grooves 96 with the confluent hole 90 as the center are formed on the side plane 94 which faces the second discharge block 82 of the second confluent block 80. From the distal ends of the radial grooves 96 to the direction of thickness of the second confluent block 80, through holes 98 are respectively formed. The through holes 98 are communicated with the above-described annular groove 86, which is formed in the second supply block 78.

In the center axis of the second discharge block 82, one through hole 100 is formed in the direction of thickness of the block. The through hole 100 becomes the second discharge flow channel 102. Moreover, in the center axis of the third discharge block 84, one through hole 104 is formed in the direction of thickness of the block. The through hole 104 becomes the third discharge flow channel 106. The second discharge flow channel 102 and the third discharge flow channel 106 are communicated with the mixing field 92.

According to the microdevice 70 configured as described above, the fluid A and the fluid B are divided into eight flows, mixed in the first stage mixing field 18 and brought into reaction and the reaction product C and the fluid D divided into four can be mixed in the second stage mixing field 92 and be brought into reaction. Accordingly, not only that the reaction can be carried out in a multistage manner, but also various modes of mixture can be adopted corresponding with properties and nature of fluid for mixture (inclusive of reaction).

Here, also in the case of the microdevice 70, as described with reference to FIGS. 2 to 7, the taperings 60 are preferably formed at the flow channel end parts of the supply flow channels in communication to the mixing field 92 so as to contract the flows. Moreover, the discharge flow channel is sized likewise the diameter of the mixing field and, moreover, is preferably tapered. It is preferable that the microdevice 70 is provided with all the properties described for the microdevice 30 as well.

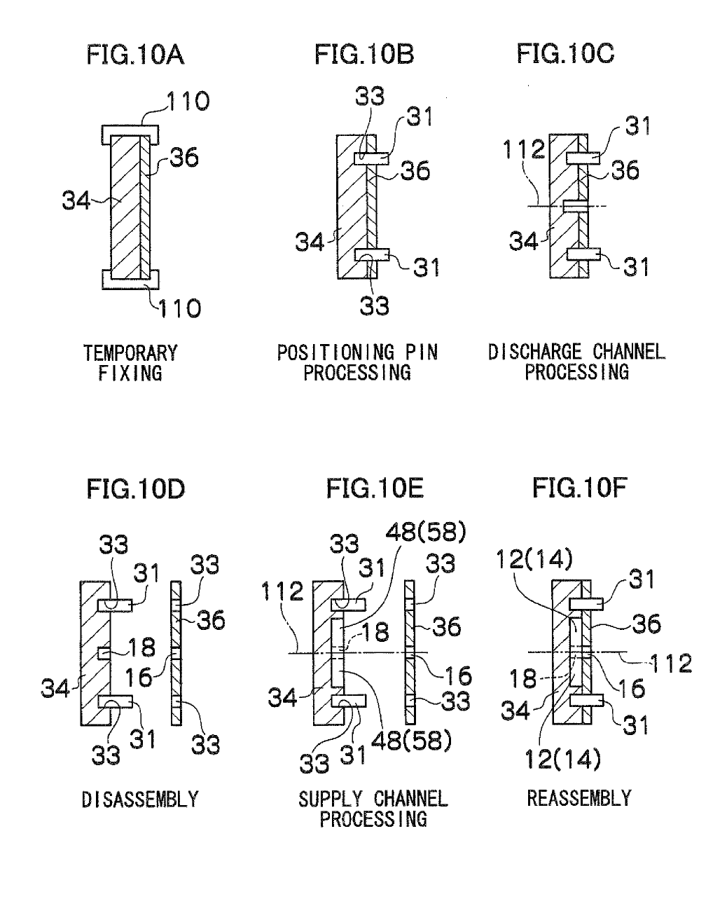

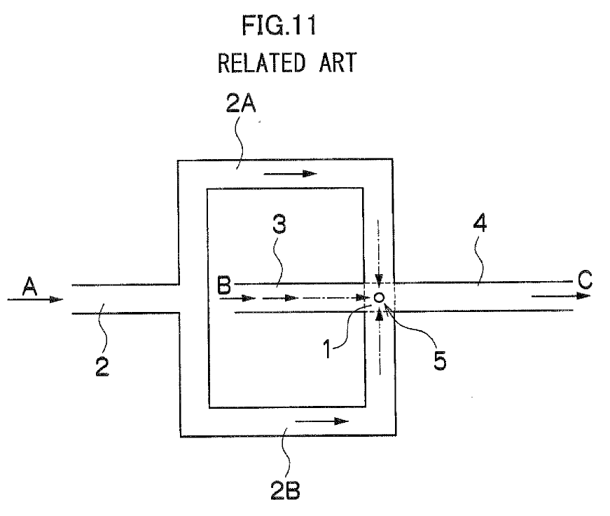

Next, a manufacturing method of the microdevices 30 and 70 of the present embodiment will be described with reference to FIGS. 10A to 10F.

The manufacturing method of the microdevices 30 and 70 of the present embodiment includes a manufacturing method of the confluent blocks 34 (74) and 80 and the discharge blocks 36 (76) and 82, which form the discharge flow channel 16 among the plurality of the above-described discoidal blocks (the supply block 32, the confluent block 34, the discharge block 36 and the like) which configure the microdevices 30 and 70. Here, in the following description, the confluent block 34 and the discharge block 36 are described as examples.

Firstly, in the first step in FIG. 10A, the mutual plate surfaces of the confluent block 34 and the discharge block 36 prior to processing with the supply flow channels 12 and 14, the mixing field 18, the discharge flow channel 16 and the like not yet undergoing processing are matched together and are temporarily bound with a temporary joint device 110 (for example, a clamp and a compact size vice).

Next, in the second step and the third step in FIG. 10B, a microdrill, for example, is used in a temporary bounded state; the pin holes 33 are provided from the side of the discharge block 36; and the pins 31 are inserted into the pin holes 33. The temporary binding device 110 used for temporary binding is then removed. Three or more pin holes 33 are preferably formed in equal distance interval on the circumference with the center axis of the mixing field 18 and the discharge flow channel 16 as the center. Thereby, the confluence block 34 and the discharge block 36 are detachably bound with the pins. Alternatively, it is also preferable that the three pins 31 are nonsymmetrically arranged, so that an error in relative direction between the confluent block 34 and the discharge block can be prevented and mistakes in assembling can be prevented. Moreover, by making the diameters of the three pins 31 different to each other, an error in relative direction between the confluent block 34 and the discharge block can be prevented.

Next, in the fourth step in FIG. 10C, with the confluent block 34 and the discharge block 36 being left bound with the pins 31, from the center position on the plate surface on the side of the discharge block 36, a microdrill, for example, is used. A hole is formed to midway of the confluent block 34 to form the discharge flow channel 16 and the mixing field 18. Thereby, the center axes 112 of the discharge flow channel 16 and the mixing field 18 are brought into matching.

Next, in the fifth step in FIG. 10D, the confluent block 34 and the discharge block 36 are temporarily disassembled, and the discharge block 36 is removed from the confluent block 34.

Next, in the sixth step in FIG. 10E, the radial grooves 48 and 58 are formed on the plane surface of the confluent block 34, which surface is on the side of the discharge block 36. The number of the radial grooves 48 and 58 are the same with the number of the supply flow channels 12 and 14. The radial grooves 48 and 58 are arranged radially from the center axis 112 of the mixing field 18 formed in the fourth step.

Next, in the sixth step in FIG. 10F, the discharge block 36 and the confluent block 34 are reassembled by binding with the pins 31. Thereby, the supply flow channels 12 and 14, the mixing field 18 and the discharge flow channel 16 are formed. Since protrusions of the pins 31 on the side of the discharge block 36 disturb the fixing of the blocks besides the confluent block 34 and the discharge block 36 with a bolt, it is preferable that the protruding portions of the pins 31 are cut out in advance.

According to the manufacturing method of the microdevice of the present embodiment, in order to improve accuracy in position at an occasion of disassembling and assembling the confluent block 34 and the discharge block 36, at first, the mixing field 18 and the discharge flow channel 16 are formed in the state where the confluent block 34 and the discharge block 36 are detachably connected with the pin holes 33 and the pins 31, so as to bring the center axes of the mixing field 18 and the discharge flow channel 16 into matching, and then, the supply flow channels 12 and 14 are formed radially from the center axes 112 of the mixing field 18. Thus, production can be carried out extremely high in accuracy in relative position between the plurality supply flow channels 12 and 14 and the mixing field 18 and in accuracy in the relative position between the mixing field 18 and the discharge flow channel 16. Accordingly, the microdevices 30 and 70 capable of carrying out uniform and rapid mixture can be produced.

Moreover, accurate positioning of the confluent block 34 and the discharge block 36 is feasible. Therefore, even if there is no engineers with advanced assembly techniques, well accurate reassembly is feasible subjected to disassembly and cleaning.

Here, in the present embodiment, the microdevices 30 and 70 have been explained with a lateral type as examples. However by making the microdevice 30 or 70 into a vertical type, disturbance of laminar flow due to specific gravity can be restrained. Consequently, in the case of fluid significantly different in specific gravity and dispersed large particles, it is possible to carry out rapid mixture in a stable manner.

### EXAMPLES

With the microdevice 30 illustrated in FIG. 1, examples of manufacturing an organic based pigment microparticles are described. However, the method will not be limited to that example.
The fluid A (organic based pigment solution) was prepared by dissolving pigment Yellow 128 (CROMOPHTAL YELLOW 8GNP, produced by Ciba Specialty Chemicals) in the amount of 3.0 g at the room temperature with dimethylsulfoxide in the amount of 45.5 mL, methanol solution of 28% sodium methoxide (produced by Wako Pure Chemical Industries) in the amount of 2.49 mL, Aqualon KH-10 (produced by Dai-ichi Kogyo Seiyaku) in the amount of 2.4 g, N-vinyl pyrrolidon (produced by Wako Pure Chemical Industries) in the amount of 0.6 g, polyvinylpyrrolidone K30 (produced by Tokyo Chemical Industry) in the amount of 0.15 g, and 1.5 g VPE0201 (produced by Wako Pure Chemical Industries). The pH of the fluid A exceeded the measurement limit (pH 14) and the measurement was impossible.

Distillated water was used as the fluid B.

The fluid A and the fluid B were caused to pass through a 0.45 μm microfilter (produced by Sartorius) and impurities such as dust were removed.

Conditions on the microdevice 30 were as follows.

(i) Each of the two fluids A and B was divided into five flows (i.e., ten flow channels in total come into confluence; incidentally, four flow channels each, that is, eight flow channels in total for the case of the apparatus in FIG. 1).

(ii) Diameter of supply flow channels 12 and 14 was 400 μm each.

(iii) Diameter of mixing field 18 was 800 μm.

(iv) Diameter of discharge flow channel 16 was 800 μm.

(v) Intersection angle of mutual center axes of the supply flow channels 12 and 14 and the discharge flow channel 16 in the mixing field 18 was 90°.

(vi) Material of the blocks was stainless steel (AISI 304).

(vii) Flow channel processing was carried out by microdischarge processing. Sealing of the four parts of the supply block 32, the confluent block 34, the first discharge block 36 and the second discharge block 37 was carried out with metal plane sealing by mirror polishing. Two tubes made of polytetrafluoroethylene with 50 cm length and 1 mm corresponding diameter were connected to the entrance of the microdevice 30 and the other ends thereof were connected to syringes, which contained the fluid A and the fluid B respectively, and were set up in pumps. A tube made of polytetrafluoroethylene with 1.5 m length and 2 mm equivalent diameter was connected to the exit of the microdevice 30. The fluid A and the fluid B were sent out at the fluid sending velocities of 150 mL/min and 600 mL/min, respectively.

The microdevice 30 (comparative example) without the taperings 60 being formed at the end parts of the supply flow channels and the microdevice 30 (example of the present invention) with the taperings 60 being formed to contract the incoming flow to the mixing field 18 to decrease the mutual diffusion distance between the fluid A and the fluid B in the mixing field 18 being decreased by half of the comparative example were used and were brought into comparison.

Consequently, with respect to the organic based pigment particle obtained by the microdevice of the comparative example, the volume average diameter Mv was 25.2 nm and the ratio of the volume average diameter Mv to the number average diameter Mn being an index of mono-dispersion properties was 1.50.

In contrast, with respect to the organic based pigment particle obtained by the microdevice of the example of the present invention, the volume average diameter Mv and the proportion of the volume average diameter Mv to the number average diameter Mn being an index of mono-dispersion properties were both smaller than the comparative example and gave rise to a good result.

It should be understood, however, that there is no intention to limit the invention to the specific forms disclosed, but on the contrary, the invention is to cover all modifications, alternate constructions and equivalents falling within the spirit and scope of the invention as expressed in the appended claims.

What is claimed is:

1. A fluid mixing method in which a plurality of fluids are distributed through respective independent supply flow channels to come into confluence in a mixing field in microspace to mix with each other to form a mixed fluid, and the mixed fluid is discharged from the mixing field through a discharge flow channel, the method comprising:
a dividing step of dividing at least one of fluids to distribute;
a flow contracting step of contracting the fluids after the dividing step immediately prior to confluence to the mixing field;
a confluence step of bringing the contracted fluids into confluence so as to intersect at one point in the mixing field to mix the fluids; and
a discharge step of discharging the mixed fluid from the mixing field.

2. The fluid mixing method as defined in claim 1, wherein the mixing field is a discoidal microspace having a diameter of not more than 1 mm.

3. The fluid mixing method as defined in claim 1, wherein in the discharge step, the mixed fluid to be discharged is contracted in a flow direction.

4. The fluid mixing method as defined in claim 1, wherein the dividing step, the flow contracting step, the confluence step and the discharge step constitute each of a plurality of units of steps, and the plurality of units of steps are consecutively carried out.

5. A microdevice, comprising:
a plurality of independent supply flow channels through which a plurality of fluids are respectively distributed;
a mixing field in microspace where the fluids distributed through the supply flow channels come into confluence to mix with each other to form a mixed fluid; and
a discharge flow channel through which the mixed fluid is discharged from the mixing field, wherein:
the supply flow channels include divided supply flow channels divided into a plurality of channels so as to divide at least one of the fluids into a plurality of fluid parts to be distributed;
the supply flow channels including the divided supply flow channels are radially arranged around the mixing field so that center axes of the supply flow channels intersect at one point in the mixing field;
at least a part of ends of the supply flow channels connected to the mixing field, taperings are formed so as to contract flows of the fluids; and
the taperings are formed to provide a corresponding diameter D1 of a virtual circle depicted by connecting the ends of the radially arranged supply flow channels each other being smaller than a corresponding diameter D2 of a virtual circle depicted by connecting ends of the radially arranged supply flow channels each other without forming the taperings.

6. The microdevice as defined in claim 5, wherein the mixing field is a discoidal microspace having a diameter of not more than 1 mm.

7. The microdevice as defined in claim 5, wherein each of the ends of the supply channels is tapered to narrow a width of the flow channel and is formed to compensate decrease in a flow channel cross-sectional area by deepening a depth of the flow channel.

8. The microdevice as defined in claim 5, wherein the corresponding diameter D1 is equal to a diameter D3 of a flow channel cross-section of the discharge flow channel.

9. The microdevice as defined in claim 5, wherein the discharge flow channel is formed to taper in a flow direction of the mixed fluid.

10. The microdevice as defined in claim 5, wherein directions of the taperings are adjusted so as to generate a swirling flow in the mixing field without moving the center axes of the supply flow channels.

11. A microdevice configured by connecting a plurality of microdevices in series, each of the microdevices being the microdevice as defined in claim 5.

12. A manufacturing method of a confluent block and a discharge block among a plurality of plate-like blocks which constitute a microdevice in which a plurality of fluids are distributed through respective independent supply flow channels to come into confluence in a mixing field in microspace to mix with each other to form a mixed fluid, and the mixed fluid is discharged from the mixing field through a discharge flow channel, the confluent block forming the mixing field and the supply flow channels in communication with the mixing field, the discharge block forming the discharge flow channel, the method comprising:
a first step of temporarily binding, with a temporary joint device, the confluent block and the discharge block prior to processing with mutual plate surfaces being matched together;
a second step of forming a plurality of pin holes on the confluent block and the discharge block temporarily bound, the pin holes to be used for detachably binding the confluent block and the discharge block with pins;
a third step of inserting the pins into the pin holes to bind the confluent block and the discharge block, and removing the temporary joint device;
a fourth step of forming a hole from a center position on a plate surface on a side of the discharge block to midway the confluent block bound with the pins, to form the discharge flow channel and the mixing field with center axes thereof being matched together;
a fifth step of temporarily disassembling the discharge block and the confluent block to remove the discharge block from the confluent block;
a sixth step of forming flow channel grooves in a same number as the supply flow channels, on a plane surface of the confluent block on a side of the discharge block radially from the center axis of the mixing field formed in the fourth step; and
a seventh step of reassembling the confluent block and the discharge block by binding with the pins.
